(19) United States
(12) Patent Application Publication
(10) Pub. No.: US 2020/0335385 A1
(43) Pub. Date: Oct. 22, 2020

(54) SUBSTRATE PROCESSING APPARATUS

(71) Applicant: Tokyo Electron Limited, Tokyo (JP)

(72) Inventors: Tetsuya SAITOU, Nirasaki City (JP); Yuichiro WAGATSUMA, Nirasaki City (JP)

(21) Appl. No.: 16/848,211

(22) Filed: Apr. 14, 2020

(30) Foreign Application Priority Data
Apr. 16, 2019 (JP) 2019-077689

(51) Int. Cl. H01L 21/687; H01L 21/67

(52) U.S. Cl. CPC H01L 21/68742; H01L 21/68735; H01L 21/68792; H01L 21/67098

(57) ABSTRACT

A substrate processing apparatus for processing a substrate includes: a stage having a through-hole penetrating the stage in a vertical direction, the stage being configured to place the substrate on an upper surface of the stage and perform at least one of heating and cooling of the substrate placed on the upper surface; a lift pin configured to be inserted into the through-hole and capable of protruding from the upper surface of the stage through the through-hole; and a support member configured to be capable of supporting the lift pin, wherein the lift pin has a flange located below a lower surface of the stage, wherein the support member is further configured to support the lift pin by engaging with the flange, and wherein the through-hole in the stage is narrower than the flange of the lift pin.

### CROSS-REFERENCE TO RELATED APPLICATION

This application is based upon and claims the benefit of priority from Japanese Patent Application No. 2019-077689, filed on Apr. 16, 2019, the entire contents of which are incorporated herein by reference.

### TECHNICAL FIELD

The present disclosure relates to a substrate processing apparatus.

### BACKGROUND

Patent Document 1 discloses a substrate processing apparatus that prevents uniformity of a substrate process from being adversely affected by wraparound of process gas or the like when processing a substrate at a high temperature. This substrate processing apparatus includes a susceptor, a lifting drive apparatus, a plurality of substrate support pins, and a movement prevention member. The susceptor is disposed horizontally and supports the substrate such that the substrate is placed on the upper surface. The lifting drive apparatus drives the susceptor up or down between a first position for supporting the substrate and a second position lower than the first position and waiting for the substrate to be supported. The substrate support pins are supported to be movable in the vertical direction with respect to the susceptor, and support the substrate when the susceptor is positioned at the second position. The movement prevention member prevents the substrate support pins from moving downward when the susceptor is moved from the first position to the second position. The susceptor has pin insertion holes for inserting the substrate support pins, and a diameter of an upper end of the substrate support pin is set to be larger than a diameter of the pin insertion hole. Thus, the substrate support pins are supported to be movable in the vertical direction with respect to the susceptor. Recesses for accommodating the upper ends of the substrate support pins having the larger diameter are formed at upper end portions of the pin insertion holes in the susceptor.

### PRIOR ART DOCUMENT

### Patent Document

(Patent Document 1) Japanese Laid-Open Patent Publication No. 11-111821

### SUMMARY

According to an embodiment of the present disclosure, a substrate processing apparatus for processing a substrate is provided. The substrate processing apparatus includes: a stage having a through-hole penetrating in a vertical direction, the stage being configured to place the substrate on an upper surface of the stage and perform at least one of heating and cooling of the substrate placed on the upper surface; a lift pin configured to be inserted into the through-hole and capable of protruding from the upper surface of the stage through the through-hole; and a support member configured to be capable of supporting the lift pin, wherein the lift pin has a flange located below a lower surface of the stage, the support member is configured to support the lift pin by engaging with the flange, and the through-hole in the stage is narrower than the flange of the lift pin.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory view schematically illustrating a configuration of a film-forming apparatus as a substrate processing apparatus according to an embodiment of the present disclosure.

FIG. 2 is a partially enlarged cross-sectional view illustrating a state inside the film-forming apparatus of FIG. 1 when a stage has been moved to a processing position.

FIG. 3 is a partially enlarged cross-sectional view illustrating a state inside the film-forming apparatus of FIG. 1 when the stage has been moved to a transport position.

FIG. 4 is a partially enlarged cross-sectional view illustrating a state inside the film-forming apparatus of FIG. 1 when a wafer W is delivered between lift pins and a wafer transport apparatus.

FIG. 5 is a view illustrating another example of the support member configured to suspend and hold the lift pins.

FIG. 6 is a view illustrating another example of the support member configured to suspend and hold the lift pins.

FIG. 7 is a plane view illustrating a modification of the support member of FIG. 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

For example, in a semiconductor device manufacturing process, a substrate process such as a film-forming process is performed on a semiconductor wafer (hereinafter, referred to as a “wafer”). This substrate process is performed using a substrate processing apparatus. When the substrate processing apparatus is of a single-wafer type that processes substrates one by one, a stage having an upper surface on which a substrate is placed is provided in the apparatus. In addition, the single-wafer-type substrate processing apparatus is provided with substrate support pins that are respectively inserted into holes formed in the stage and configured to deliver a substrate between a substrate transport apparatus configured to transport a substrate and the stage. The substrate support pins are fixed, for example, to a bottom wall of a processing container configured to accommodate a substrate therein.

During a substrate process, the substrate placed on the stage may be heated or cooled via the stage. In this case, when the substrate support pins are fixed to the bottom wall of the processing container as described above, a relative displacement occurs between the holes in the stage and the substrate support pins due to thermal expansion and thermal contraction of the stage. Therefore, if the substrate support pins are fixed to the bottom wall of the processing container as described above, the substrate support pins may be damaged when the substrate support pins and the stage are relatively moved for the delivery of the substrate or the like. Therefore, in Patent Document 1, the diameter of the upper end portion of the substrate support pin is set to be larger than the diameter of the pin insertion hole in the susceptor without fixing the substrate support pins to the bottom wall of the processing container, whereby the substrate support pins are supported by the susceptor.

However, when the diameter of the upper end portion of the substrate support pin is increased, recesses having a diameter larger than that of the upper end portion need to be provided at the upper surface of the stage in order to accommodate the upper end portions, respectively. When such recesses are provided, in-plane uniformity of a temperature of the substrate on the stage is impaired.

Therefore, a technique according to the present disclosure improves the in-plane uniformity of the temperature of the substrate when the substrate placed on the stage is heated or cooled on the stage.

Hereinafter, the substrate processing apparatus according to the present embodiment will be described with reference to the drawings. In the specification and drawings, elements having substantially the same functional configurations will be denoted by the same reference numerals and redundant explanations will be omitted.

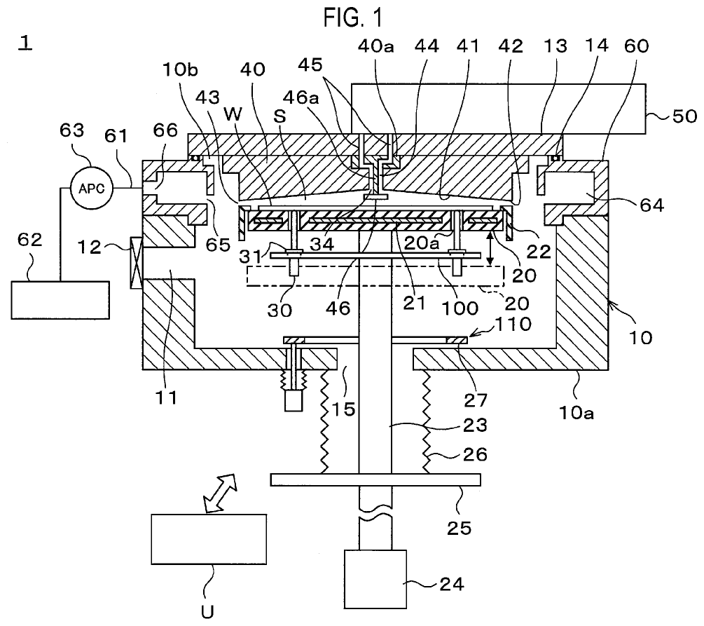

FIG. 1 is an explanatory view schematically illustrating a configuration of a film-forming apparatus as a substrate processing apparatus according to an embodiment of the present disclosure, in which a part of the film-forming apparatus is illustrated in a cross section.

The film-forming apparatus 1 of FIG. 1 includes a processing container 10 configured to be capable of being depressurized and to accommodate therein a wafer W as a substrate.

The processing container 10 includes a container body 10a formed in a cylindrical shape and having a bottom.

A loading/unloading port 11 for a wafer W is provided at the side wall of the container body 10a, and the loading/unloading port 11 is provided with a gate valve 12 configured to open/close the loading/unloading port 11. Above the loading/unloading port 11, an exhaust duct 60 to be described below, which forms a portion of the side wall of the container body 10a, is provided. An opening 10b is provided in the upper portion of the container body 10a, that is, in the exhaust duct 60, and a lid 13 is provided so as to close the opening 10b. An O-ring 14 is provided between the exhaust duct 60 and the lid 13 so as to hermetically maintain the inside of the processing container 10.

A stage 20 having an upper surface on which a wafer W is placed horizontally is provided in the processing container 10. A heater 21 configured to heat the wafer W is provided inside the stage 20. When the wafer W needs to be cooled, a cooling mechanism is provided inside the stage 20. Both the heater 21 and the cooling mechanism may be provided inside the stage 20 so that both heating and cooling of the wafer W can be performed.

The stage 20 is provided with a cover member 22 such that the cover member 22 covers a region on the outer peripheral side of a region on the upper surface of the stage 20 where the wafer W is placed and the peripheral surface thereof in the peripheral direction.

To a central portion of the lower surface of the stage 20, an upper end of a support shaft member 23 as a stage support member, which penetrates the bottom wall of the processing container 10 through an opening 15 formed in the bottom wall of the processing container 10 and extends in the vertical direction, is connected. A lower end of the support shaft member 23 is connected to a drive mechanism 24 as a movement mechanism. The drive mechanism 24 generates a driving force for raising/lowering and rotating the support shaft member 23, and includes, for example, an air cylinder (not illustrated) and a motor (not illustrated). As the support shaft member 23 moves up or down by the driving of the drive mechanism 24, the stage 20 may move up or down between a transport position indicated by the two-dot chain line and a processing position above the transport position. The transport position refers to a position where the stage 20 stands by when the wafer W is being delivered between a transport mechanism (not illustrated) of the wafer W, which enters the processing container 10 from the loading/unloading port 11 of the processing container 10, and lift pins 30 to be described below. In addition, the processing position is a position where a process is performed on the wafer W. In addition, as the support shaft member 23 rotates about an axis thereof by the driving of the drive mechanism 24, the stage 20 rotates about the axis.

A flange 25 is provided on the support shaft member 23 outside the processing container 10. A bellows 26 is provided between the flange 25 and a penetrating portion of the support shaft member 23 in the bottom wall of the processing container 10 so as to surround an outer peripheral portion of the support shaft member 23. Thus, an airtightness of the processing container 10 is maintained.

In addition, the stage 20 has a plurality of through-holes 20a penetrating the stage 20 vertically. In the stage 20, each through-hole 20a is provided with a lift pin 30, which is inserted into the through-hole 20a. The lift pins 30 are provided in order to deliver the wafer W between the stage 20 and a wafer transport apparatus (not illustrated) inserted into the processing container 10 from outside the processing container 10. The lift pins 30 are configured to be capable of protruding from the upper surface of the stage 20 at the above-described transport position through the through-holes 20a, respectively.

A shape of the lift pins 30, a support structure for the lift pins 30, and the structure for raising or lowering the lift pins 30 will be described later.

In addition, a cap member 40 is provided between the stage 20 and the lid 13 in the processing container 10 so as to face the stage 20 in order to form a processing space S between the cap member 40 and the stage 20. The cap member 40 is fixed to the lid 13 with bolts (not illustrated).

An inverted bowl-shaped recess 41 is formed at a lower portion of the cap member 40. At an outer side of the recess 41, a flat rim 42 is formed.

In addition, the processing space S is formed by the upper surface of the stage 20 located at the aforementioned processing position and the recess 41 of the cap member 40. A height of the stage 20 when the processing space S is formed is set such that a gap 43 is formed between a lower surface of the rim 42 of the cap member 40 and an upper surface of the cover member 22. The recess 41 is formed such that, for example, a volume of the processing space S is as small as possible and a gas replacement property when replacing a processing gas with a purge gas becomes good.

A gas introduction path 44 for introducing the processing gas or the purge gas into the processing space S is formed at a central portion of the cap member 40. The gas introduction path 44 penetrates the central portion of the cap member 40, and a lower end of the gas introduction path 44 faces the central portion of the wafer W on the stage 20. Further, a flow path forming member 40a is fitted into the central portion of the cap member 40, and an upper side of the gas introduction path 44 is branched by the flow path forming member 40a, so that each of the branched gas introduction paths communicates with a gas introduction path 45 which penetrates the lid 13.

A dispersion plate 46 configured to disperse the gas ejected from the gas introduction path 44 into the processing space S is provided below the lower end of the gas introduction path 44 in the cap member 40. The dispersion plate 46 is fixed to the cap member 40 via a support rod 46a.

The gas introduction path 45 is provided with a gas introduction mechanism 50 configured to introduce a processing gas such as TiCl₄ gas, NH₃ gas, N₂ gas for purging or the like from gas supply sources (not illustrated) to the processing container 10. An O-ring (not illustrated) is provided between the gas introduction mechanism 50 and the processing container 10, specifically, between the gas introduction mechanism 50 and the lid 13 in order to hermetically maintain the inside of the processing container 10.

In addition, one end of an exhaust pipe 61 is connected to the exhaust duct 60 of the container body 10a. The other end of the exhaust pipe 61 is connected to an exhaust apparatus 62 constituted by, for example, a vacuum pump. An APC valve 63 configured to adjust a pressure in the processing space S is provided at an upstream side of the exhaust apparatus 62 of the exhaust pipe 61.

The exhaust duct 60 is formed by forming a gas flow passage 64 having a rectangular vertical cross section in an annular shape. A slit 65 is formed on an inner peripheral surface of the exhaust duct 60 over the entire circumference thereof. An exhaust port 66 is provided at an outer wall of the exhaust duct 60, and the exhaust pipe 61 is connected to the exhaust port 66. The slit 65 is formed at a position corresponding to the aforementioned gap 43 formed when the stage 20 is raised to the aforementioned processing position. Accordingly, a gas in the processing space S reaches the gas flow passage 64 of the exhaust duct 60 through the gap 43 and the slit 65 by operating the exhaust apparatus 62, and is exhausted through the exhaust pipe 61.

The film-forming apparatus 1 configured as described above is provided with a controller U. The controller U is constituted by, for example, a computer including a CPU, memory, or the like, and includes a program storage (not illustrated). The program storage stores a program and the like for realizing wafer processes to be described later in the film-forming apparatus 1. The program may be recorded in a computer-readable storage medium, and may be installed in the controller U from the storage medium. In addition, a part or all of the program may be implemented by dedicated hardware (a circuit board).

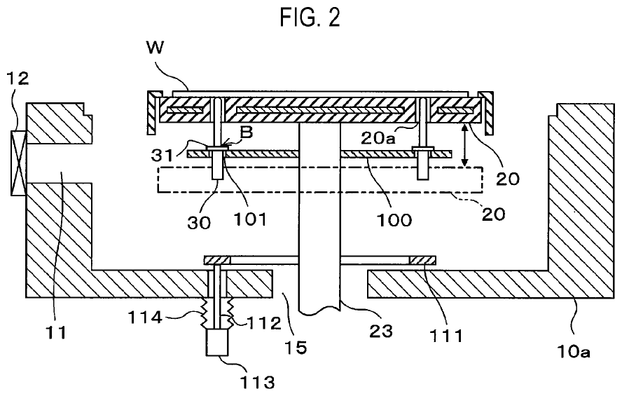

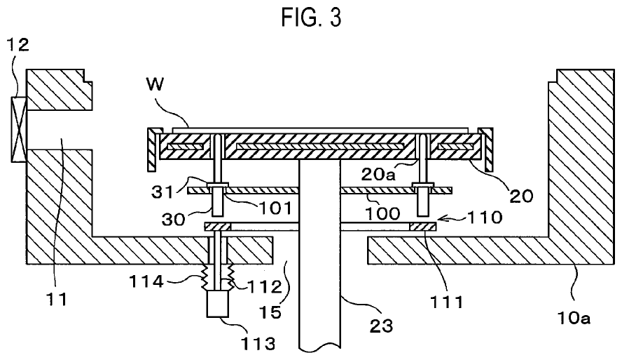

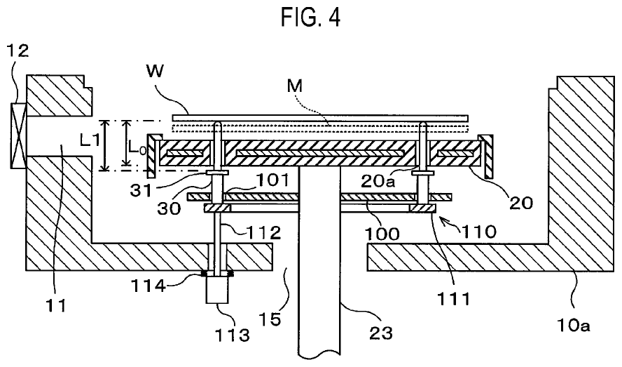

Next, a shape of the lift pins 30, a support structure of the lift pins 30, and the structure configured to raise or lower the lift pins 30 will be described with reference to FIG. 1 and using FIGS. 2 to 4. FIGS. 2 to 4 are partially enlarged cross-sectional views respectively illustrating states inside the film-forming apparatus 1 of FIG. 1. FIG. 2 illustrates a state when the stage 20 has been moved to the processing position, FIG. 3 illustrates a state when the stage 20 has been moved to the transport position, and FIG. 4 illustrates a state when a wafer W is delivered between the lift pins 30 and the wafer transport device.

As illustrated in FIG. 1, the lift pins 30 are rod-shaped members each having a flange 31 located below the lower surface of the stage 20, and are made of, for example, alumina. The flange 31 is formed at a position spaced apart from an upper end surface and a lower end of the lift pin 30, that is, substantially at the center of the lift pin 30. A portion of each lift pin 30 above the flange 31 is inserted into a corresponding one of the through-holes 20a in the stage 20. In addition, as illustrated in FIG. 2, a portion of each lift pin 30 below the flange 31 is inserted into an insertion hole 101 in a support member 100 to be described below. Further, each lift pin 30 is formed such that the portion thereof below the flange 31 is thicker than the portion thereof above the flange 31.

Each through-hole 20a in the stage 20 into which the lift pin 30 is inserted as described above is formed to be narrower than the flange 31 of the lift pin 30. In other words, an inner diameter of each through-hole 20a in the stage 20 is set smaller than the diameter of the flange 31 of the lift pin 30. Specifically, for example, the diameter of the portion of the lift pin 30 above the flange 31 may be 1.0 mm to 3.0 mm, and the diameter of the flange 31 may be twice or more the diameter of the flange 31. The inner diameter of the through-hole 20a in the stage 20 may be set to, for example, 1.2 to 1.5 times the diameter of the portion of the lift pin 30 above the flange 31, and may be, for example, 2.0 to 4.0 mm.

A support member 100 and a pin movement mechanism 110 are provided for the lift pins 30. As illustrated in FIG. 1, the support member 100 is provided between the stage 20 and the bottom wall of the processing container 10, and the pin movement mechanism 110 is provided between the support member 100 and the bottom wall of the processing container 10. In other words, the support member 100 is provided between the stage 20 and the pin movement mechanism 110 in the processing container 10.

The support member 100 is a member configured to be capable of supporting the lift pins 30. Specifically, the support member 100 is configured to be capable of supporting the lift pins 30 by engaging with the flanges 31 of the lift pins 30. More specifically, as illustrated in FIG. 2, the support member 100 has insertion holes 101 into which the portions of lift pins 30 below the flanges 31 are inserted respectively. The support member 100 is configured such that the lift pins 30 may be suspended and held as the upper surface of the support member 100 around the insertion holes 101 and the lower surfaces of the flanges 31 of the lift pins 30 are in contact with each other. The inner diameter of each insertion hole 101 is set to, for example, 1.2 to 1.5 times the diameter of the portion of the corresponding lift pin 30 below the flange 31 that is inserted into the insertion hole 101.

In the state in which the stage 20 is moved to the processing position as illustrated in FIG. 2, the flanges 31 of the lift pins 30 and the support member 100 are engaged with each other. The length of the lift pins 30 and the positions of the flange 31 are set so as to satisfy the following conditions (A) and (B) in this state.

(A) The upper end surfaces of the lift pins 30 do not protrude from the upper surface of the stage 20 (in the example of the drawing, the upper end surfaces of the lift pins 30 and the upper surface of the stage 20 being substantially flush with each other).

(B) The upper end surfaces of the lift pins 30 are located above the lower surface of the stage 20, and the lift pins 30 are at least partially inserted into the respective through-holes 20a in the stage 20.

The engagement between the flanges 31 of the lift pins 30 and the support member 100 described above is not released only by moving the stage 20 to the transport position, as illustrated in FIG. 3. In the state in which the stage 20 is moved to the transport position, the engagement is released when the lift pins 30 are raised by the pin movement mechanism 110 as illustrated in FIG. 4. However, in the process of moving the stage 20 to the transport position, the lower surfaces of the lift pins 30 and the upper surface of the pin movement mechanism 110 come into contact with each other, and the further downward movement of the lift pins 30 is hindered. Thus, when the movement of the stage 20 to the transport position is completed, the engagement may be released.

The support member 100 is fixed with respect to the stage 20. Specifically, the support member 100 is provided at, for example, the support shaft member 23 connected to the stage 20. Accordingly, the support member 100 is vertically moved integrally with the stage 20 by the drive mechanism 24, and is rotated integrally with the stage 20.

The support member 100 is formed of a plate-shaped member having a circular shape in a plane view using a low thermal conductivity material such as alumina or quartz. By using the low thermal conductive material for the support member 100 as described above, for example, it is possible to prevent a heat of the stage 20 to which the support member 100 is attached from being taken out by the support member 100. In addition, when an iron-based material or the like is used for the support member 100, iron may be mixed into a film formed by the film-forming apparatus 1. However, the aforementioned mixing may be prevented by using alumina or quartz for the support member 100.

The pin movement mechanism 110 is configured to be capable of supporting the lift pins 30, and moves the supported lift pins 30 in the vertical direction. The pin movement mechanism 110 supports the lift pins 30 by engaging with the lower end portions of the lift pins 30. Specifically, the pin movement mechanism 110 include a contact member 111. Lower end surfaces of the lift pins 30, which are inserted into the insertion holes 101 in the support member 100 and exposed from the lower surface of the support member 100, come into contact with an upper surface of the contact member 111, whereby the pin movement mechanism 110 supports the lift pins 30. The contact member 111 is formed of, for example, a member having an annular shape in the plane view.

A support column 112 is provided on the lower surface of the contact member 111, and the support column 112 penetrates the bottom wall of the processing container 10 and is connected to a drive mechanism 113 provided outside the processing container 10. The drive mechanism 113 generates a driving force for moving the support column 112 up or down. As the support column 112 moves up or down by the driving of the drive mechanism 113, the contact member 111 moves up or down, whereby the lift pins 30 supported by the contact member 111 move up or down independent of the stage 20. In particular, as the support column 112 moves upward by the driving of the drive mechanism 113, the lift pins 30 move upward, and as illustrated in FIG. 4, upper end portions of the lift pins 30 protrude from the upper surface of the stage 20, which has moved to the transport position.

Here, a distance from the upper end surface of the lift pin 30 to the lower surface of the stage 20 when the lift pin 30 protrudes most from the upper surface of the stage 20, that is, a length of the portion of the lift pin 30 capable of passing through the through-hole 20a in the stage 20 is set to be L₀. A length L1 of the portion of the lift pin 30 above the flanges 31 (more specifically, a distance from the upper end surface of the lift pin 30 to the upper surface of the flange 31) is set to be 1.1 to 1.5 times the length L₀.

A bellows 114 is provided between the drive mechanism 113 and the penetrating portion of the support column 112 in the bottom wall of the processing container 10 so as to surround the outer peripheral portion of the support column 112. Thus, the airtightness of the processing container 10 is maintained.

Next, wafer processes performed using the film-forming apparatus 1 will be described.

First, the gate valve 12 is opened, and the wafer transport mechanism M (see FIG. 4) holding a wafer W is inserted into the processing container 10 from a transport chamber (not illustrated) in a vacuum atmosphere adjacent to the processing container 10 through the loading/unloading port 11. Then, the wafer W is transported above the stage 20 that has been moved to the aforementioned standby position. Next, the lift pins 30 suspended and held by the support member 100 are moved upward by the pin movement mechanism 110. As a result, the suspension is released, the lift pins 30 protrude from the upper surface of the stage 20 by a predetermined distance, and the wafer W is delivered onto the lift pins 30. Thereafter, the wafer transport mechanism M is pulled out of the processing container 10, and the gate valve 12 is closed. At the same time, the lift pins 30 are lowered by the pin movement mechanism 110, and the stage 20 is raised by the drive mechanism 24. As a result, the support of the lift pins 30 by the pin movement mechanism 110 is released, the lift pins 30 are suspended and held again by the support member 100, and the upper end portions of the lift pins 30 are in the state of being received in the through-holes 20a in the stage 20 without protruding from the upper surface. In this state, the wafer W is placed on the stage 20. Next, the inside of the processing container 10 is adjusted to a predetermined pressure, the stage 20 is moved to the processing position by the drive mechanism 24, and the processing space S is formed.

In this state, via the gas introduction mechanism 50, N₂ gas serving as a purge gas is supplied to the processing space S and TiCl₄ gas and NH₃ gas are alternately and intermittently supplied to the processing space S, such that a TiN film is placed on the wafer W through an ALD method. During this film formation, the wafer W is heated by the stage 20, such that, for example, the temperature of the wafer W (specifically, the temperature of the stage 20) becomes 300 degrees C. to 600 degrees C.

After the formation of the TiN film through the ALD method described above is terminated, the stage 20 on which the wafer W is placed is lowered to the transport position. Next, the lift pins 30 are raised by the pin movement mechanism 110. Thus, the suspension of the lift pins 30 by the support member 100 is released, and the lift pins 30 are moved upward by the pin movement mechanism 110. As a result, the suspension is released, the lift pins 30 protrude from the upper surface of the stage 20 by a predetermined distance, and the wafer W is delivered onto the lift pins 30. Thereafter, the gate valve 12 is opened, and the wafer transport mechanism M that does not hold a wafer W is inserted into the processing container 10 through the loading/unloading port 11. The wafer transport mechanism M is inserted to a gap between the wafer W held by the lift pins 30 and the stage 20 at the transport position. Next, the lift pins 30 are lowered by the pin movement mechanism 110, and the wafer W on the lift pins 30 is delivered to the wafer transport mechanism M. Then, the wafer transport mechanism M is pulled out of the processing container 10, and the gate valve 12 is closed. Thus, a series of wafer processes are completed.

Then, the aforementioned series of wafer processes are performed on another wafer W.

In the series of wafer processes, the lift pins 30 are always partially inserted into the respective through-holes 20a in the stage 20, and the lift pins 30 are not pulled out of the through-holes 20a.

As described above, in the present embodiment, in the film-forming apparatus 1 in which the wafer W placed on the stage 20 is heated on the stage 20, the flange 31 is provided on each lift pin 30 below the lower surface of the stage 20, and the support member 100 supports the lift pin 30 by engaging with the flange 31 of the lift pin 30. That is, the lift pins 30 are not fixed to the support member 100 or the like. Accordingly, the lift pins 30 are not damaged or smooth operation of raising or lowering the lift pins 30 is not impaired by thermal expansion of the stage 20. In the present embodiment, each through-hole 20a (particularly, the upper end thereof) in the stage 20 into which a lift pin 30 is inserted is formed to be narrower than the flange 31 of the lift pin 30. Therefore, according to the present embodiment, it is possible to prevent the temperatures of the portions of the wafer W corresponding to the through-holes 20a from being lowered as compared with, for example, the case where the through-holes 20a are formed to be larger than the flanges 31 of the lift pins 30. Therefore, it is possible to improve in-plane uniformity of the temperature of the wafer W.

In the present embodiment, the support structure of the lift pins 30 is the structure in which the support member 100 suspends and holds the lift pins 30, and which is a simple structure that, in order to support the lift pins 30, does not use an operation member such as a clamp that may serve as a foreign matter emission source. In the case where the aforementioned operation member is used, there is a possibility that the operation member serves as a foreign matter emission source. In the support structure of the lift pins 30 according to the present embodiment, as described above, since a member serving as a foreign matter emission source is not used, it is possible to prevent a TiN film formed on a wafer W from being degraded.

Further, in the present embodiment, each lift pin 30 is formed such that the portion thereof below the flange 31 is thicker than the portion thereof above the flange 31. Therefore, when the lift pins 30 are supported by the pin movement mechanism 110 from below, it is possible to stably support the lift pins 30.

Further, in the present embodiment, the length L1 of the portion of the lift pin 30 above the flange 31 is set to be 1.1 to 1.5 times the length L₀ of the portion of the lift pin 30 capable of passing through the corresponding through-hole 20a in the stage 20. That is, in the present embodiment, the length L1 of the portion of the lift pin 30 above the flange 31 is set as short as possible. Therefore, when the lift pins 30 come into contact with the inner walls of the through-holes 20a in the stage 20 when the lift pins 30 are moved up or down, and the like, stress generated in the lift pins 30 is small. Therefore, since the lift pin 30 is less likely to be damaged by the stress, it is possible to reduce the diameter of the lift pin 30, and to reduce the inner diameter of the through-hole 20a in the stage 20. Accordingly, it is possible to further improve the in-plane uniformity of the temperature of the wafer W.

Further, in the present embodiment, the lift pins 30 are supported by the support member 100 provided between the stage 20 and the pin movement mechanism 110 in the vertical direction. Therefore, it is possible to reduce a length from the upper end of the lift pin 30 to the flange 31 as compared with that in the configuration in which the lift pins 30 are supported by the pin movement mechanism 110 without the support member 100. Therefore, similarly to the above, since the lift pins 30 are less likely to be damaged by the stress, it is possible to reduce the diameter of the lift pin 30, and to reduce the inner diameter of the through-hole 20a in the stage 20. Accordingly, it is possible to further improve the in-plane uniformity of the temperature of the wafer W.

The upper portion of the lift pin 30 above the flange 31 and the lower portion of the lift pin 30 including the flange 31 may be integrally formed by integral molding, cutting-out, bonding, or the like. However, the upper portion and the lower portion of the lift pin 30 may be configured separately, and the upper portion may be supported to be movable along an upper surface of the lower portion. When the upper portion and the lower portion in each lift pin 30 are formed integrally, and when the lift pin 30 comes into contact with the inner wall of the through-hole 20a in the stage 20, stress may be generated at a boundary (see symbol “B” in FIG. 2) between the upper portion of the lift pin 30 above the flange 31 and the flange 31. However, by configuring the upper portion and the lower portion of the lift pin 30 separately as described above, it is possible to prevent the generation of stress.

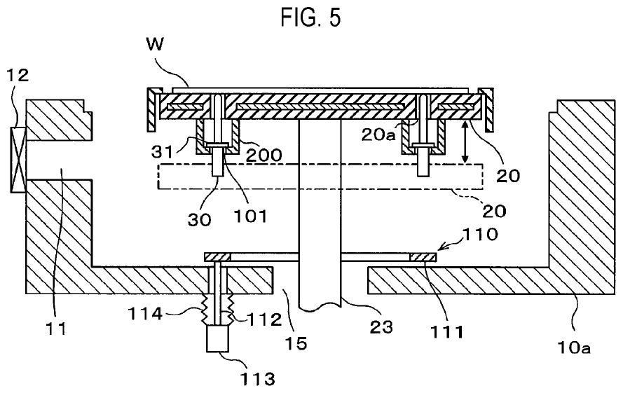

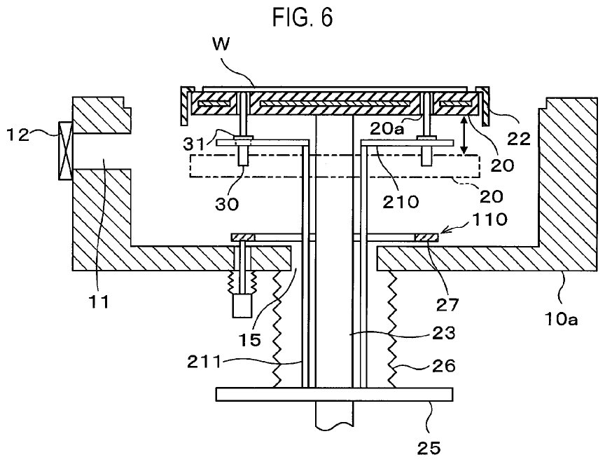

FIGS. 5 and 6 are views illustrating other examples of support members configured to suspend and hold the lift pins 30.

Although the support member 100 is attached to the support shaft member 23 in the aforementioned examples, the attachment position of the member configured to suspend and hold the lift pins 30 is not limited thereto.

Support members 200 of the example of FIG. 5 are attached to the stage 20. Since it is possible to reduce a size of the support member 200, it is possible to reduce a heat capacity of the support members 200. Therefore, since it is possible to reduce an amount of heat taken by the support members 200, it is possible to heat a wafer W efficiently.

A support member 210 is not attached to the support shaft member 23 or the stage 20 in the example of FIG. 6, but is attached to the flange 25 serving as a fixed member. Specifically, the support member 210 is attached to the flange 25 via leg portions 211 extending in the vertical direction. Since the support member 210 is not attached to the support shaft member 23 and the stage 20, the heat of the stage 20 is not taken away by the support member 210 directly or via the support shaft member 23. Thus, it is possible to heat the wafer W more efficiently.

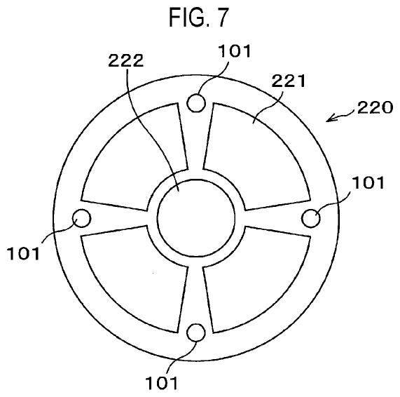

FIG. 7 is a plane view illustrating a modification of the support member 100 in the example of FIG. 1. In the example of FIG. 1, the support member 100 supports the lift pins 30, is attached to the support shaft member 23, and is formed of a plate-shaped member having a circular shape in the plane view. However, a shape of the member that supports the lift pins 30 and is attached to the support shaft member 23 is not limited to thereto.

In an example of FIG. 7, a support member 220 has a shape having weight-reducing portions 221. The weight-reducing portions 221 are formed in regions other than the regions engaged with the lift pins 30. Specifically, the weight-reducing portions 221 are formed in regions other than regions where the insertion holes 101 into which the lift pins 30 are inserted are formed and a region where a shaft hole 222 for the support shaft member 23 is formed in the plane view. The weight-reducing portions 221 may be through-holes or recesses.

Since the support member 220 has the weight-reducing portions 221, it is possible to reduce a heat capacity of the support member 220. Therefore, since it is possible to reduce an amount of the heat taken by the support member 220, it is possible to heat a wafer W efficiently.

In addition, the weight-reducing portions may be provided at the support members attached to the stage 20 or the flange 25 as in the examples of FIGS. 5 and 6.

In the example described above, the pin movement mechanism 110 configured to move the lift pins 30 in the vertical direction is provided, but the pin movement mechanism 110 may be omitted when the following conditions (C) and (D) are satisfied.

(C) The wafer transport mechanism M is configured to be movable in the vertical direction.

(D) The upper end portions of the lift pins 30 protrude from the upper surface of the stage 20 when the stage 20 has been moved to the transport position.

In this case, in the process in which the stage 20 is moved to the transport position, the lower surfaces of the lift pins 30 come into contact with, for example, the bottom wall of the processing container 10 and further downward movement of the lift pins 30 is hindered, whereby the upper end portions of the lift pins 30 protrude from the upper surface of the stage 20 in the state in which the stage 20 has been moved to the transport position.

In the aforementioned example, in a series of wafer processes, the lift pins 30 are always partially inserted into the through-holes 20a in the stage 20, and the lift pins 30 are not pulled out from the through-holes 20a. However, in a series of wafer processes, there may be a timing at which the lift pins 30 are pulled out from the through-holes 20a in the stage 20.

For example, in the aforementioned example, the support member of the lift pins 30 is configured to rotate integrally with the stage 20. However, when the support member does not rotate integrally with the stage 20, the lift pins 30 are pulled out of the through-holes 20a in the stage 20 at the timing at which the stage 20 is moved to the processing position.

However, when the support member of the lift pins 30 and the stage 20 are configured to rotate integrally, an alignment between the through-holes 20a in the stage 20 and the lift pins 30 may be unnecessary.

In addition, even when the stage 20 is not rotated, there may be no timing at which the lift pins 30 are pulled out from the through-holes 20a in the stage 20 in a series of wafer processes in some embodiments. This is because the positions of the through-holes 20a in the stage 20 may be displaced from the positions of the lift pins 30 due to thermal expansion of the stage 20, and the like after the lift pins 30 are pulled out. In this case, even if the lift pins 30 are suspended and held (even if the lift pins 30 are held in a float structure), it may be difficult to re-insert the lift pins 30 into the through-holes 20a in the stage 20.

In the foregoing, the film formation is performed using the ALD method, but the technique according to the present disclosure is also applicable to a case where the film formation is performed using a CVD method. For example, the technique according to the present disclosure is applicable to the case where an Si film or an SiN film is formed through the CVD method using an Si-containing gas.

In the foregoing, the film-forming apparatus has been described as an example, but the technique according to the present disclosure is also applicable to a substrate processing apparatus including a stage and performing processes other than the film-forming process. For example, the present disclosure is also applicable to an inspection apparatus that performs an inspection processing.

It shall be understood that the embodiments disclosed herein are illustrative and are not limiting in all aspects. The aforementioned embodiments may be omitted, replaced, or modified in various forms without departing from the scope and spirit of the appended claims.

The following configurations also belong to the technical scope of the present disclosure.

(1) A substrate processing apparatus for processing a substrate, including: a stage that has a through-hole penetrating the stage in a vertical direction, the stage being configured to place the substrate on an upper surface of the stage and perform at least one of heating and cooling of the substrate thus placed; a lift pin configured to be inserted into the through-hole and capable of protruding from the upper surface of the stage through the through-hole; and a support member configured to be capable of supporting the lift pin, wherein the lift pin has a flange located below a lower surface of the stage, wherein the support member is further configured to support the lift pin by engaging with the flange, and wherein the through-hole in the stage is narrower than the flange of the lift pin.

According to the above (1), the flange is provided at the lift pin below the lower surface of the stage, and the support member supports the lift pin by being engaged with the flange of the lift pin. Therefore, the lift pin is not damaged or smooth operation of raising or lowering the lift pin is not impaired by the thermal expansion of the stage. In addition, the through-hole in the stage into which the lift pin is inserted is formed narrower than the flange of the lift pin. Therefore, since it is possible to suppress a decrease in the temperature of the portion of the substrate corresponding to the through-hole, it is possible to improve the in-plane uniformity of the temperature of the substrate.

(2) The substrate processing apparatus of above (1), further including a pin movement mechanism configured to move the lift pin in the vertical direction, wherein the support member is provided between the stage and the pin movement mechanism.

According to the above (2), it is possible to reduce the length from the upper end of the lift pin to the flange, as compared with the configuration in which the support member is omitted and the lift pin is supported by the pin movement mechanism. Therefore, when the lift pin comes into contact with the inner wall of the through-hole when the lift pin moves up and down, it is possible to reduce stress generated in the lift pin. Therefore, it is possible to reduce the diameter of the lift pin, and reduce the inner diameter of the through-hole. Accordingly, it is possible to further improve the in-plane uniformity of the temperature of the substrate.

(3) The substrate processing apparatus of the above (1) or (2), wherein the flange is formed at a position spaced apart from an upper end and a lower end of the lift pin.

(4) The substrate processing apparatus of the above (3), wherein the lift pin is formed such that a portion of the lift pin below the flange is formed to be thicker than a portion of the lift pin above the flange.

According to the above (4), it is possible to stably support the lift pin when the lift pin is supported from below.

(5) The substrate processing apparatus of the above (3) or (4), wherein the support member has an insertion hole into which a portion of the lift pin below the flange is inserted.

According to the above (5), it is possible to suspend and hold the lift pin by the support member.

(6) The substrate processing apparatus of any one of the above (1) to (5), further including a movement mechanism configured to move the stage in the vertical direction.

(7) The substrate processing apparatus of any one of the above (1) to (6), wherein a length of a portion of the lift pin above the flange is 1.1 to 1.5 times a length of a portion of the lift pin that is capable of passing through the through-hole in the stage.

According to the above (7), it is possible to further improve the in-plane uniformity of the temperature of the substrate.

(8) The substrate processing apparatus of any one of the above (1) to (7), wherein a diameter of a portion of the lift pin inserted into the through-hole in the stage is 1.0 to 3.0 mm, and an inner diameter of the through-hole is 2.0 to 4.0 mm.

(9) The substrate processing apparatus of any one of the above (1) to (8), further including: a stage support member having an upper end connected to the lower surface of the stage and configured to support the stage, wherein the support member is attached to the stage support member.

(10) The substrate processing apparatus of any one of the above (1) to (8), wherein the support member is attached to the lower surface of the stage.

(11) The substrate processing apparatus of any one of the above (1) to (8), further including a stage support member having an upper end connected to the lower surface of the stage and configured to support the stage, and a fixed member to which the stage support member is fixed, wherein the support member is attached to the fixed member.

(12) The substrate processing apparatus of any one of the above (1) to (11), wherein the support member has a weight-reducing portion in a region other than a region in which the support member is engaged with the lift pin.

According to the (12), it is possible to reduce the heat capacity of the support member. Therefore, it is possible to heat or cool the substrate efficiently.

According to the present disclosure, it is possible to improve the in-plane uniformity of the temperature of the substrate when the substrate placed on the stage is heated or cooled on the stage.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for processing a substrate, the substrate processing apparatus comprising:
a stage having a through-hole penetrating the stage in a vertical direction, the stage being configured to place the substrate on an upper surface of the stage and perform at least one of heating and cooling of the substrate placed on the upper surface;
a lift pin configured to be inserted into the through-hole and capable of protruding from the upper surface of the stage through the through-hole; and
a support member configured to be capable of supporting the lift pin,
wherein the lift pin has a flange located below a lower surface of the stage,
wherein the support member is further configured to support the lift pin by engaging with the flange, and
wherein the through-hole in the stage is narrower than the flange of the lift pin.

2. The substrate processing apparatus of claim 1, further comprising:
a pin movement mechanism configured to move the lift pin in the vertical direction,
wherein the support member is provided between the stage and the pin movement mechanism.

3. The substrate processing apparatus of claim 2, wherein the flange is formed at a position spaced apart from an upper end and a lower end of the lift pin.

4. The substrate processing apparatus of claim 3, wherein the lift pin is formed such that a portion of the lift pin below the flange is formed to be thicker than a portion of the lift pin above the flange.

5. The substrate processing apparatus of claim 4, wherein the support member has an insertion hole into which the portion of the lift pin below the flange is inserted.

6. The substrate processing apparatus of claim 5, further comprising a movement mechanism configured to move the stage in the vertical direction.

7. The substrate processing apparatus of claim 6, wherein a length of the portion of the lift pin above the flange is 1.1 to 1.5 times a length of a portion of the lift pin that is capable of passing through the through-hole in the stage.

8. The substrate processing apparatus of claim 7, wherein a diameter of a portion of the lift pin inserted into the through-hole in the stage is 1.0 to 3.0 mm, and an inner diameter of the through-hole is 2.0 to 4.0 mm.

9. The substrate processing apparatus of claim 8, further comprising:
a stage support member having an upper end connected to the lower surface of the stage and configured to support the stage,
wherein the support member is attached to the stage support member.

10. The substrate processing apparatus of claim 9, wherein the support member has a weight-reducing portion in a region other than a region in which the support member is engaged with the lift pin.

11. The substrate processing apparatus of claim 3, wherein the support member has an insertion hole into which a portion of the lift pin below the flange is inserted.

12. The substrate processing apparatus of claim 1, wherein the flange is formed at a position spaced apart from an upper end and a lower end of the lift pin.

13. The substrate processing apparatus of claim 12, wherein the lift pin is formed such that a portion of the lift pin below the flange is formed to be thicker than a portion of the lift pin above the flange.

14. The substrate processing apparatus of claim 1, further comprising: a movement mechanism configured to move the stage in the vertical direction.

15. The substrate processing apparatus of claim 1, wherein a length of a portion of the lift pin above the flange is 1.1 to 1.5 times a length of a portion of the lift pin that is capable of passing through the through-hole in the stage.

16. The substrate processing apparatus of claim 1, wherein a diameter of a portion of the lift pin inserted into the through-hole in the stage is 1.0 to 3.0 mm, and an inner diameter of the through-hole is 2.0 to 4.0 mm.

17. The substrate processing apparatus of claim 1, further comprising:
a stage support member having an upper end connected to the lower surface of the stage and configured to support the stage,
wherein the support member is attached to the stage support member.

18. The substrate processing apparatus of claim 1, wherein the support member is attached to the lower surface of the stage.

19. The substrate processing apparatus of claim 1, further comprising:
a stage support member having an upper end connected to the lower surface of the stage and configured to support the stage; and
a fixed member to which the stage support member is fixed,
wherein the support member is attached to the fixed member.

20. The substrate processing apparatus of claim 1, wherein the support member has a weight-reducing portion in a region other than a region in which the support member is engaged with the lift pin.
